(19) United States
(12) Patent Application Publication
(10) Pub. No.: US 2007/0170813 A1
(43) Pub. Date: Jul. 26, 2007

(54) Surface acoustic wave device and method of manufacturing the same

(76) Inventors: Ryouichi Takayama, Osaka (JP); Atsushi Matsui, Osaka (JP)

Correspondence Address: RATNERPRESTIA, P.O. BOX 980, VALLEY FORGE, PA, 19482, US

(21) Appl. No.: 10/590,642

(22) PCT Filed: Feb. 21, 2006
(86) PCT No.: PCT/JP06/03023

§ 371 Date: Aug. 24, 2006

(30) Foreign Application Priority Data
Mar. 3, 2005 (JP) 2005-058552

(51) Int. Cl. H03H 9/25

(52) U.S. Cl. 310/313 R

(57) ABSTRACT

A surface acoustic wave device includes a piezoelectric substrate, a comb-shaped electrode formed on a first principal face of the piezoelectric substrate, and a supporting substrate bonded to a second principal face of the piezoelectric substrate. The second principal face of the piezoelectric substrate is bonded to the supporting substrate via a metal layer. A method of manufacturing the surface acoustic wave device includes the steps of: forming a first metal layer on the second principal face of the piezoelectric substrate, forming a second metal layer on a principal face of the supporting substrate, activating the surfaces of the first and second metal layers in plasma atmosphere, bonding the first and second metal layers together at room temperature, and forming the comb-shaped electrode on the first principal face of the piezoelectric substrate.

### TECHNICAL FIELD

The present invention relates to surface acoustic wave devices to be used in mobile telephones among others, and it also relates to a method of manufacturing the same devices.

### BACKGROUND ART

Recently compact and lightweight surface acoustic wave devices have been widely used in electronic apparatuses such as a variety of mobile communication terminals. Among other these devices, surface acoustic wave filters formed of lithium tantalate (hereinafter simply referred to as LT) substrate are widely employed in the radio circuit of mobile telephone systems working in the frequency range between 800 MHz and 2 GHz. The LT substrate often employs an LT substrate having X-axis propagation of surface acoustic wave in 39° Y-cut LT (hereinafter referred to simply as 39° YLT), namely, this LT substrate is cut out from Y-plane at rotating angle of 39° on X-axis toward Z-axis.

However, the 39° YLT substrate has a greater thermal expansion coefficient along the propagating direction of surface acoustic wave, and the elastic constant per se varies depending on temperature, so that the frequency characteristics of the filter becomes somewhat greater such as −36 ppm/K with respect to temperature change. The conventional surface acoustic wave devices, as discussed above, have problems with temperature characteristics.

Take the transmitting filter employed in PCS (personal communication services) of the USA as an example, the center frequency at room temperature of this filter is 1.88 GHz, and it varies approx. ±3.3 MHz in the range of room temperature ±50° C., namely, 6.6 MHz wide. In the case of the PCS, the interval between the transmission band and the reception band is as narrow as 20 MHz. On top of that, dispersion of the frequency caused by the manufacturing should be taken into consideration, so that there is only 10 MHz interval practically between the transmission band and the reception band. If the transmission band is needed to work at overall temperatures (room temperature ±50° C.), a sufficient attenuated amount cannot be expected on the reception side.

To overcome this problem, i.e. to improve the temperature characteristics, a substrate having another coefficient of linear expansion is bonded to 39° YLT substrate. However, this conventional method needs heat treatment in order to obtain bonding strength, and it also requires some special washing. As a result, thermal strain is obliged to remain in the conventional surface acoustic wave devices.

The prior art related to the present invention is disclosed in, e.g. Unexamined Japanese Patent Publication No. 2004-297693.

### DISCLOSURE OF INVENTION

A surface acoustic wave device of the present invention comprises the following elements:
a piezoelectric substrate;
a comb-shaped electrode formed on a first principal face of the piezoelectric substrate; and
a supporting substrate bonded, via a metal layer, to a second principal face of the piezoelectric substrate.

The foregoing structure allows obtaining surface acoustic wave devices excellent in electrical characteristics, and yet, narrowing the disperse of frequency characteristics change of the devices, which change is caused by temperature.

A method of manufacturing the surface acoustic wave device of the present invention comprises the steps of:
forming a first metal layer on a second principal face of a piezoelectric substrate having a first and the second principal faces;
forming a second metal layer on a principal face of a supporting substrate;
activating surfaces of the first metal layer and the second metal layer in plasma atmosphere;
bonding the first metal layer and the second metal layer together at room temperature; and
forming a comb-shaped electrode on the first principal face of the piezoelectric substrate.

The foregoing method allows manufacturing surface acoustic wave devices excellent in electrical characteristics, and yet, narrowing the disperse of their frequency-characteristics changes caused by temperature.

### BRIEF DESCRIPTION OF THE DRAWINGS

FIG. 1 shows a sectional view of a surface acoustic wave device in accordance with an embodiment of the present invention.

FIG. 2 shows a sectional view of another surface acoustic wave device in accordance with an embodiment of the present invention.

FIG. 3A schematically illustrates a method of manufacturing a surface acoustic wave device in accordance with an embodiment of the present invention.

FIG. 3B further schematically illustrates the method.

FIG. 3C further schematically illustrates the method.

### DESCRIPTION OF REFERENCE MARKS

11, 21 piezoelectric substrate
12, 22 comb-shaped electrode
13, 23 supporting substrate
14 metal layer
15, 25 through-hole
16, 26 electric conductor (conducting layer)
17, 27 heat dissipating layer
24a first metal layer
24b second metal layer
31, 41 first principal face of piezoelectric substrate
32, 42 second principal face of piezoelectric substrate
50 principal face of supporting substrate

### DESCRIPTION OF PREFERRED EMBODIMENT

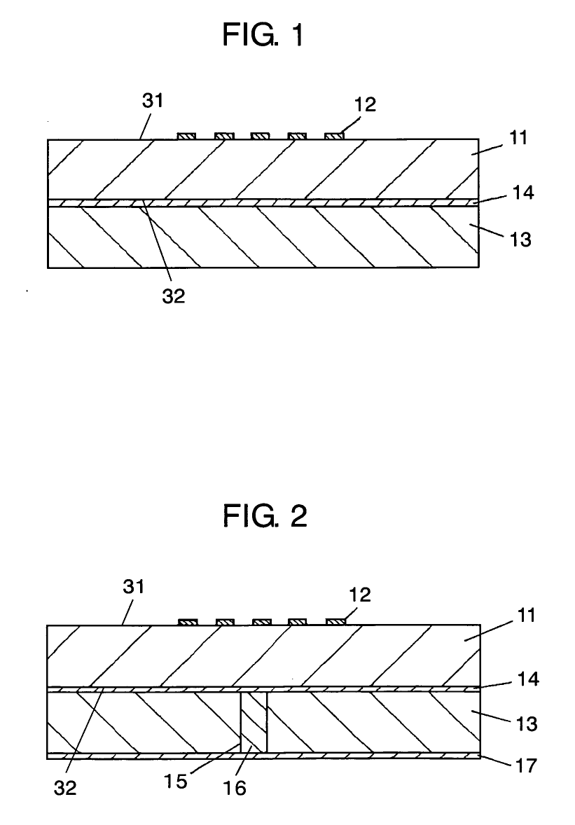

An exemplary embodiment of the present invention is demonstrated hereinafter with reference to the accompanying drawings. FIG. 1 shows a sectional view of a surface acoustic wave device in accordance with the embodiment of the present invention. The surface acoustic wave device shown in FIG. 1 of the present invention comprises the following element:
piezoelectric substrate 11;
comb-shaped electrode 12 formed on first principal face 31 of piezoelectric substrate 11; and
supporting substrate 13 bonded, via metal layer 14, to second principal face 32 of piezoelectric substrate 11.

The foregoing surface acoustic wave device is further detailed hereinafter. Piezoelectric substrate 11 is made from rotated Y-cut lithium tantalate, to be more specific, 39° YLT. Comb-shaped electrode 12 is provided onto first principal face 31 of piezoelectric substrate 11. Supporting substrate 13 is made from sapphire or the like. Second principal face 32 of piezoelectric substrate 11 and supporting substrate 13 are bonded together via metal layer 14 made of gold or the like.

The foregoing structure allows the difference in linear expansion coefficient between piezoelectric substrate 11 and supporting substrate 13 to narrow the disperse of frequency characteristics change, which is caused by temperature. Piezoelectric substrate 11 and supporting substrate 13 are bonded together via metal layer 14 in between at room temperature, so that no thermal strain remains and stable electrical characteristics can be expected. The bonding at room temperature means that no heating is applied to piezoelectric substrate 11 or supporting substrate 13 expressly for bonding.

FIG. 2 shows a sectional view of another surface acoustic wave device in accordance with the embodiment of the present invention. The surface acoustic wave device shown in FIG. 2 comprises the following elements:
piezoelectric substrate 11;
comb-shaped electrode 12 formed on first principal face 31 of piezoelectric substrate 11; and
supporting substrate 13 bonded, via metal layer 14, to second principal face 32 of piezoelectric substrate 11, and having through hole 15, at least of which inner wall is provided with electrically conductive layer 16 made of electric conductor such as nickel. Metal layer 14 is thus electrically coupled to conductive layer 16.

As shown in FIG. 2, heat dissipating layer 17 made of metal is preferably formed on supporting layer 13 to be coupled electrically to conductive layer 16.

The foregoing structure allows dissipating the heat generated at comb-shaped electrode 12 from dissipating layer 17 via metal layer 14 and conductive layer 16. As a result, the surface acoustic wave device shown in FIG. 2 can improve the stability of electrical characteristics and withstand a greater electric power consumption. Electromagnetic shielding can be also improved.

Bonding a piezoelectric substrate and another substrate together invites mismatching in acoustic impedance on the interface, and unnecessary bulk wave reflects on the interface, so that the frequency characteristics tends to become spurious, i.e. unnecessary components other than target frequencies tend to occur.

To overcome this problem, metal layer 14 is removed its metal in part on second principal face 32 of piezoelectric substrate 11 so that some parts of layer 14 having no metal are formed and metal layer 14 thus becomes striped pattern or meshed pattern. This structure allows scattering the unnecessary bulk waves and reducing affect of the spurious components. As discussed above, metal layer 14 adhering to second principal face 32 of piezoelectric substrate 11 is removed its metal in part.

In this case, the stripes or meshes of metal layer 14 preferably extend in the following direction: On the surface of piezoelectric substrate 11, the surface acoustic wave propagates along the direction at right angels to the extending direction of comb-shaped electrode 12. The extending direction of the stripes or meshes of metal layer 14 is preferably set somewhat between in parallel with or at right angles, namely, slanting with respect to the perpendicular direction to the extension of comb-shaped electrode 12. The extending direction of the stripes or meshes is thus preferably set as crossing with an underpass to the extension of comb-shaped electrode 12 with piezoelectric substrate 11 in between. This structure allows further reducing the affect of unnecessary bulk waves. The pitch of the stripes or meshes is preferably set an order of the wavelength of the surface acoustic wave, and yet use of plural pitches is preferable.

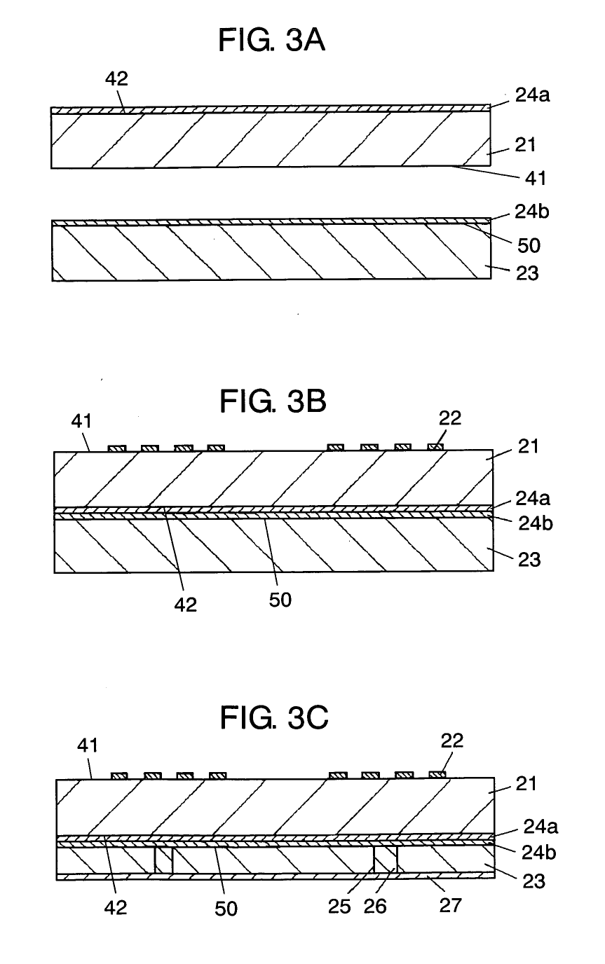

A method of manufacturing the surface acoustic wave device of the present invention is demonstrated hereinafter with reference to FIG. 3A-FIG. 3C. The method comprises the following steps:
forming first metal layer 24a on second principal face 42 of piezoelectric substrate 21 having first and second principal faces 41 and 42;
forming second metal layer 24b on principal face 50 of supporting substrate 23;
activating the surfaces of first metal layer 24a and second metal layer 24b in plasma atmosphere;
bonding first metal layer 24a and second metal layer 24b together at room temperature; and
forming comb-shaped electrode 22 on first principal face 41 of piezoelectric substrate 21.

The manufacturing method is further detailed. As shown in FIG. 3A, gold (Au) is sputtered in approx. 100 nm thickness as first metal layer 24a on second principal face 42 of piezoelectric substrate 21 which is formed of a wafer-like 39° YLT in approx. 0.35 mm thickness. In a similar way, gold (Au) is sputtered in approx. 100 nm thickness as second metal layer 24b on principal face 50 of supporting substrate 23 which is formed of a wafer-like silicone substrate in approx. 0.3 mm thickness. The faces of first metal layer 24a and second metal layer 24b are preferably polished as mirror finish.

The surfaces of first metal layer 24a and second metal layer 24b are purified and activated in a chamber by argon-gas in plasma atmosphere. Then the two metal layers confront each other, and a pressure is applied to the two confronting layers to be bonded together as shown in FIG. 3B.

Then an electrode, such as comb-shaped electrode 22, of a surface acoustic wave device is formed on first principal face 41 of piezoelectric substrate 21. However, in this case, the total thickness of piezoelectric substrate 21 and supporting substrate 23 becomes as thick as approx. 0.65 mm, so that either one of the substrates or both of them are preferably ground or polished to be thinner.

First metal layer 24a can be formed of another metal than that of second metal layer 24b; however, both the layers preferably employ the same metal because the two layers can be bonded together with ease.

On second principal face 42 of piezoelectric substrate 21, first metal layer 24a has preferably no adhesion of metal in part. To achieve this structure, in the case of using gold for first metal layer 24a, a resist pattern is firstly formed on second principal face 42 of piezoelectric substrate 21, then the gold is sputtered thereon, and the gold is removed in part by lift-off for first metal layer 24a to be mesh-shaped.

Roughening the underside of the piezoelectric substrate has been used for scattering the bulk wave; however, the surface type of the underside due to this roughening cannot be determined arbitrarily. In this embodiment, patterns can be formed by photolithography, so that a necessary surface type can be formed in response to the characteristics of the piezoelectric substrate. Although the conventional roughening process sometimes incurs cracks on the piezoelectric substrate due to thermal load, in this embodiment, the underside of the piezoelectric substrate can be polished as mirror-finish which is resistant to the thermal load.

Second metal layer 24b can be uniformly formed on principal face 50 of supporting substrate 23. Bonding first metal layer 24a and second metal layer 24b together at room temperature allows scattering unnecessary bulk-waves and reducing the affect of the spurious components. Use of the metal to be etched with ease such as aluminum for first metal layer 24a allows forming a given pattern by etching.

As shown in FIG. 3C, piezoelectric substrate 21 is bonded to supporting substrate 23, and an electrode of the surface acoustic wave device such as comb-shaped electrode 22 is formed on piezoelectric substrate 21. Then principal face 50 of supporting substrate 23 is ground or polished to be thinner when it is needed, and a resist pattern is formed on supporting substrate 23, which is then etched by dry-etching. Through-hole 25 extending to second metal layer 24b is thus formed. The resist pattern is then removed, and conductive metal such as titanium or nickel is sputtered in approx. 1 μm thickness onto principal face 50 of supporting substrate 23. The metal such as titanium or nickel thus covers second metal layer 24b, the inner wall of through-hole 25, and supporting substrate 23, so that conductive layer 26 and heat dissipating layer 27 are formed. Plating is preferably provided on top of these layers so that through-hole 25 can be filled up with conductive layer 26.

The step of forming through-hole 25 and conductive layer 26 can be carried out either before or after the step of forming comb-shaped electrode 22 on first principal face 41 of piezoelectric substrate 21.

Finally, the substrates bonded together are cut into pieces of a given size, so that individual surface acoustic wave devices are obtainable. The manufacturing method discussed above allows obtaining highly reliable surface acoustic wave devices, of which frequency characteristic change due to temperature can be suppressed within a narrow disperse.

### INDUSTRIAL APPLICABILITY

The present invention provides surface acoustic wave devices, of which in frequency characteristic change due to temperature is narrowly dispersed, and of which electrical characteristics is improved. The surface acoustic wave devices of the present invention are thus industrially useful.

1. A surface acoustic wave device comprising:
a piezoelectric substrate;
a comb-shaped electrode formed on a first principal face of the piezoelectric substrate; and
a supporting substrate bonded to a second principal face of the piezoelectric substrate,
wherein the second principal face of the piezoelectric substrate is bonded to the supporting substrate via a metal layer.

2. The surface acoustic wave device of claim 1, wherein the supporting substrate includes a through-hole and an electric conductor provided inside the through-hole, and the electric conductor is electrically coupled to the metal layer.

3. The surface acoustic wave device of claim 1, wherein the metal layer is removed the metal in part.

4. The surface acoustic wave device of claim 1, wherein the piezoelectric substrate employs rotated Y-cut lithium tantalate.

5. The surface acoustic wave device of claim 1, the supporting substrate employs a substrate made of sapphire.

6. The surface acoustic wave device of claim 1, wherein the metal layer employs gold.

7. A method of manufacturing a surface acoustic wave device, the method comprising the steps of:
forming a first metal layer on a second principal face of a piezoelectric substrate having a first principal face and the second principal face;
forming a second metal layer on a principal face of a supporting substrate;
activating surfaces of the first and the second metal layers in plasma atmosphere;
bonding the first metal layer and the second metal layers together at room temperature; and
forming a comb-shaped electrode on the first principal face of the piezoelectric substrate.

8. The method of claim 7, wherein the first and the second metal layers are made of identical metal.

9. The method of claim 7 further comprising the steps of:
forming the first metal layer, of which metal is removed in part by lift-off, on the second principal face of the piezoelectric substrate;
forming the second metal layer entirely on the principal face of the supporting substrate; and
bonding the first metal layer and the second metal layer together at room temperature.

10. The method of claim 7 further comprising the steps of:
removing the metal in part from the first metal layer by etching after forming the first metal layer entirely on the second principal face of the piezoelectric substrate;
forming the second metal layer entirely on the principal face of the supporting substrate; and
bonding the first metal layer and the second metal layer together at room temperature.

11. The method of claim 7 further comprising the steps of:
bonding the first metal layer and the second metal layer together at room temperature;
providing the supporting substrate with a through-hole; and
forming an electric conductor covering at least an inner wall of the through-hole by at least one of sputtering and plating, and electrically coupling the electrical conductor covering the inner wall of the through-hole to the second metal layer.
